(19) United States
(12) Patent Application Publication
(10) Pub. No.: US 2009/0014067 A1
(43) Pub. Date: Jan. 15, 2009

(54) PHOTOVOLTAIC ASSEMBLY

(75) Inventor: GA-LANE CHEN, Santa Clara, CA (US)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/106,506

(22) Filed: Apr. 21, 2008

(30) Foreign Application Priority Data
Jul. 13, 2007 (CN) 200710201068.6

(51) Int. Cl. H01L 31/028; H01L 31/04; H01L 31/0304; H01L 31/0296

(52) U.S. Cl. 136/258; 136/259

(57) ABSTRACT

A photovoltaic assembly includes a photovoltaic panel and a light leveling element. The photovoltaic panel includes a plurality of spaced photosensitive regions for receiving and converting light energy into electric energy. The light leveling element is disposed above the photovoltaic panel. The light leveling element includes a base, a plurality of first lenses and a plurality of second lenses. The first lenses are arranged on a central portion of the base. The second lenses are disposed on a peripheral portion of the base. The first and the second lenses are vertically aligned with the respective photosensitive regions. The refraction indices of the first lenses are less than that of the second lenses.

### BACKGROUND

1. Technical Field

The invention relates to energy conversion assemblies, and particularly to a photovoltaic assembly.

2. Description of Related Art

Currently, solar energy is considered a renewable and clean energy source, and can also be used as an alternative source of energy other than fossil fuel. Solar energy is generally produced by photovoltaic cells, as known as solar cells. The photovoltaic cell or the solar cell is a device that converts light into electrical energy using the photoelectric effect.

Generally, the solar cell includes a large-area p-n junction made from silicon. Particularly, the solar cell generally includes a layer of n-type silicon, a layer of p-type silicon, and a pair of electrodes. The layer of n-type silicon contacts the layer of p-type silicon and the p-n junction is formed therebetween. The pair of electrodes is electrically connected to the layer of n-type silicon and the layer of p-type silicon. In use, the electrodes are connected to an external load.

In order to increase the energy conversion efficiency, the solar cell further includes a converging lens, which is configured to concentrate the sunlight to a solar panel of the solar cell. However, when the light passes through the converging lens onto the solar panel of the solar cell, vignetting is unintentionally and undesirably generated and causes a reduction of brightness at the periphery portion of the solar panel. That is, luminous flux at the periphery portion of the solar panel is different from that at the central portion of the solar panel. Thus, energy conversion efficiency of the solar panel is inconsistent.

What is needed, therefore, is a photovoltaic assembly having improved and uniform energy conversion efficiency.

### SUMMARY

A photovoltaic assembly is provided. In one embodiment, the photovoltaic assembly includes a photovoltaic panel and a light leveling element. The photovoltaic panel includes a plurality of spaced photosensitive regions for receiving and converting light energy into electric energy. The light leveling element is disposed above the photovoltaic panel. The light leveling element includes a base, a plurality of first lenses and a plurality of second lenses. The first lenses are arranged on a central portion of the base. The second lenses are disposed on a peripheral portion of the base. The first and the second lenses are vertically aligned with the respective photosensitive regions. The refraction indices of the first lenses are less than that of the second lenses.

Advantages and novel features of the present photovoltaic assembly will become more apparent from the following detailed description of preferred embodiments when taken in conjunction with the accompanying drawings.

### BRIEF DESCRIPTION OF THE DRAWINGS

The components in the drawing are not necessarily drawn to scale, the emphasis instead being placed upon clearly illustrating the principles of the present invention.

FIG. 1 is a schematic view of a photovoltaic assembly in accordance with a preferred embodiment of the present invention.

FIG. 2 is a cross-sectional view of a photovoltaic panel of FIG. 1 along a line II-II.

FIG. 3 is a schematic view of an optical path when light passes through a first lens and falls onto a photovoltaic panel of FIG. 1.

FIG. 4 is a schematic view of an optical path when light passes through a second lens and falls onto a photovoltaic panel of FIG. 1.

Corresponding reference characters indicate corresponding parts throughout the drawings. The exemplifications set out herein illustrate at least one preferred embodiment of the present photovoltaic assembly, in one form, and such exemplifications are not to be construed as limiting the scope of the invention in any manner.

### DETAILED DESCRIPTION OF THE EMBODIMENT

Reference will now be made to the drawings to describe embodiments of the present photovoltaic assembly in detail.

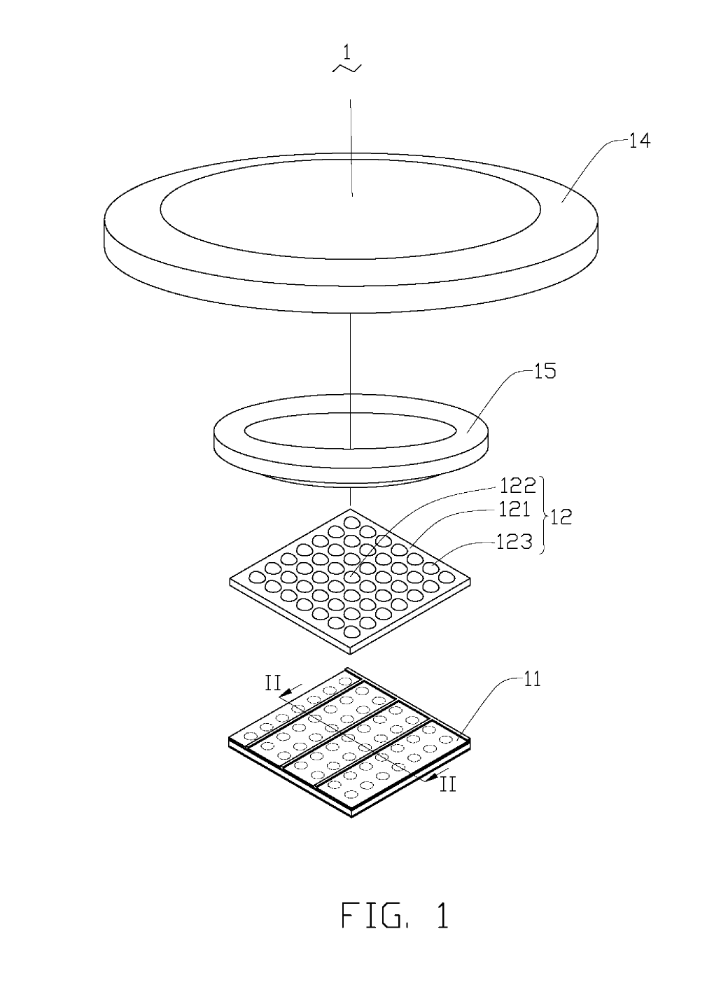

Referring to FIG. 1, a photovoltaic assembly 1 includes a photovoltaic panel 11 and a light leveling element 12. The light leveling element 12 is disposed above the photovoltaic panel 11.

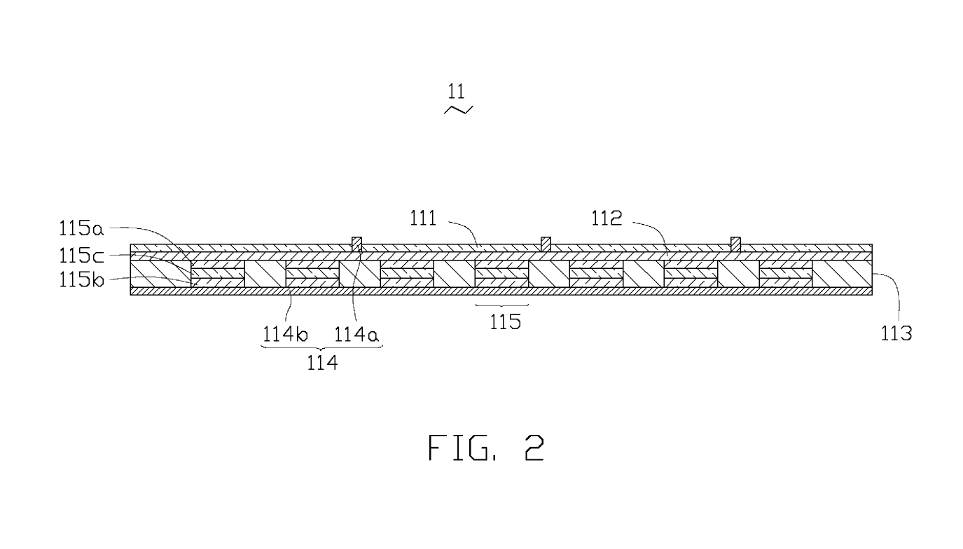

Referring to FIG. 2, the photovoltaic panel 11 includes a light-permeable substrate 111, an electrically conductive layer 112, a photovoltaic layer 113 and a pair of electrodes 114. The electrically conductive layer 112 is laminated on the light-permeable substrate 111 and the photovoltaic layer 113 is laminated on the electrically conductive layer 112. The light-permeable substrate 111 is made of glass and the electrically conductive layer 112 is made of indium tin oxide (ITO). The pair of electrodes 114 includes a front electrode 114a and a back electrode 114b disposed at opposite sides of the photovoltaic layer 113. In the present embodiment, the electrodes 114 are made of metals with high electrical conductivity, such as aluminum (Al), silver (Ag) or copper (Cu). In addition, the front electrode 114a can be formed in a finger-shaped or a comb-shaped. Thus, the front electrode 114a is embedded in one portion of the light-permeable substrate 111 contacting with the electrically conductive layer 112.

The photovoltaic layer 113 is configured to convert light energy into electrical energy. Referring to FIG. 2, the photovoltaic layer 113 has a thickness ranging from 0.6 micro meter to 10 micro meter. The photovoltaic layer 113 includes a plurality of photosensitive regions 115, which is configured for absorbing light, in particular to, absorbing the wavelength of solar light. Particularly, the photosensitive regions 115 are equidistantly spaced from each other and arranged in columns and rows. In addition, the photosensitive regions 115 are connected in series. Each of the photosensitive regions 115 of the photovoltaic layer 113 includes a first semiconductor layer 115a and a second semiconductor layer 115b stacked with each other. The front electrode 114a and the back electrode 114b are electrically connected to the first semiconductor 115a and the second semiconductor 115b, respectively.

In the present embodiment, the photovoltaic layer 113 is made of material selected from a group consisting of silicon, such as single-crystal silicon, amorphous silicon, or polycrystalline silicon, III-V compound semiconductor, such as gallium arsenide (GaAs), indium phosphide (InP), or indium gallium phosphide (InGaP), and II-VI compound semiconductor, such as cadmium telluride (CdTe), or copper indium selenide (CuInSe2). Particularly, the first semiconductor 115a is an n-type semiconductor while the second semiconductor 115b is a p-type semiconductor.

In the present embodiment, the photovoltaic layer 113 made of amorphous silicon is taken as an example. In such case, the amorphous silicon is formed by a process of plasma enhanced chemical vapor deposition. The n-type semiconductor is obtained by adding an impurity of valence-five atoms, that is, an n-type dopant into one side of the amorphous silicon. Then, the p-type semiconductor is obtained by adding an impurity of valence-three atoms, that is, a p-type dopant into opposite sides of the amorphous silicon. The n-type semiconductor has higher electron concentration than the p-type semiconductor. That is, the p-type semiconductor has an abundance of holes. In practice, the electrons diffuse from the n-type semiconductor into the p-type semiconductor and recombine with holes in the p-type semiconductor. However, such diffusion does not occur indefinitely due to an electric field, which is created by the imbalance of charge carriers immediately either side of a boundary between the n-type semiconductor and the p-type semiconductor. Thus, a depletion region is formed and also known as p-n junction 115c. The electric field established across the p-n junction 115c promotes an electrical current to flow in only one direction across the p-n junction 115c.

The photovoltaic panel 11 further includes an anti-reflection layer (not shown) disposed on the light-permeable substrate 111. Particularly, the anti-reflection layer is coated on a light incident surface of the light-permeable substrate 111 to increase the luminous flux entering the photovoltaic panel 11. In the present embodiment, the anti-reflection layer is made of silicon dioxide (SiO₂) or magnesium fluoride (MgF₂).

Referring to FIG. 1, the light leveling element 12 disposed above the photovoltaic panel 11 includes a base 121, a plurality of first lenses 122 and a plurality of second lenses 123. The base 121 is pervious to the light. The first lenses 122 and the second lenses 123 are vertically aligned with the respective photosensitive regions 115 of the photovoltaic panel 11.

In the present embodiment, the first lenses 122 are disposed on a central portion of the base 121. The second lenses 123 are disposed on a periphery portion of the base 121. In addition, the refraction indices of the first lenses 122 are less than that of the second lenses 123. That is, the lenses 123 disposed away from the central portion of the base 121 have larger refraction indices than the lenses 122 disposed close to the central portion of the base 121. Change in the refraction index of the lens is relative to the distance from the center of the light leveling element 12 to the lens and is corresponding to the luminous flux distributed on the light leveling element 12. In the present embodiment, the refraction indices of the lenses can gradually increase from the central portion of the light leveling element 12 toward the peripheral portion of the light leveling element 12.

The light leveling element 12 can be formed by the processes of welding or hot pressing. In practice, the lenses 122, 123 with different reflective indices are arranged on the base 121. After that, the lenses 122, 123 are adhesively fixed to the base 121 of the light leveling element 12 by a heating process.

Additionally, the photovoltaic assembly 1 can further include a converging lens 14 disposed above the light leveling element 12. The converging lens 14 is configured for focusing the light passing therethrough. Moreover, the photovoltaic assembly 1 further includes a diverging lens 15 disposed between the converging lens 14 and the light leveling element 12. The diverging lens 15 is configured to emanate a converged light from the converging lens 14. In such case, the converging lens 14 or the diverging lens 15 can be a sphere lens or an aspherical lens.

When a light beam passes through the converging lens 14 and the diverging lens 15, the converging lens 14 converges the light beam onto the diverging lens 15. The diverging lens 15 then emanates the converged light beam perpendicularly onto the surface of the light leveling element 12. The light leveling element 12 converges the emanated light from the diverging lens 15 onto the photosensitive regions 115 of the photovoltaic panel 11. Therefore, solar energy is converted into electricity by the photovoltaic panel 11 and then the electricity is transmitted to an external load connected to the electrodes 114.

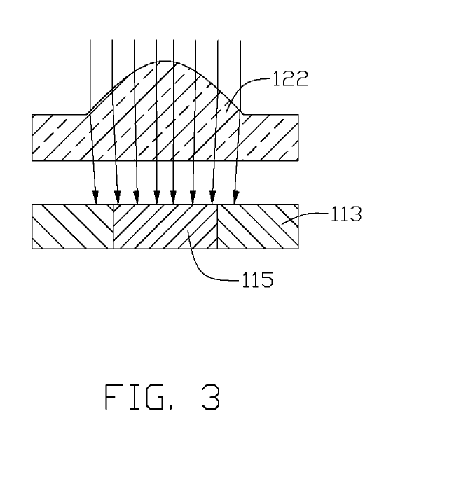

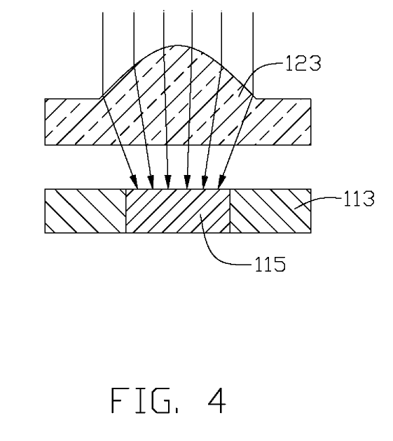

Referring to FIG. 3 and FIG. 4, schematic views of optical paths when light passes through one of the first lens 122 and one of the second lens 123, respectively, are shown. In the present embodiment, the first lens 122 has a lower refraction index and the second lens 123 has a larger refraction index. Therefore, the second lens 123 has a shorter focal length than the first lens 122. Referring to FIG. 3, when light passes through the first lens 122, most portion of the light is received by the photosensitive region 115 disposed corresponding to the first lens 122 while the remaining portion of the light falls on the area other than the photosensitive region 115. Referring to FIG. 4, when light passes through the second lens 123, majority of light is received by the photosensitive regions 115 disposed corresponding to the second lens 123. That is, amount of light received by the photosensitive region 115 is controllable. In particular, the central portion of the photovoltaic panel 11 is modulated to receive relatively less light than the peripheral region of the photovoltaic panel 11.

In conclusion, by way of disposing the lenses 122, 123 with different reflective indices, the light passing through the light leveling element 12 is distributed uniformly on the photovoltaic panel 11. That is, luminous flux entering the central portion of the photovoltaic panel 11 and the peripheral region of the photovoltaic panel 11 is equally adjusted. As a result, the energy conversion efficiency of the photovoltaic assembly 1 is consistent. Furthermore, the photovoltaic assembly 1 has improved energy conversion efficiency.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A photovoltaic assembly, comprising:
a photovoltaic panel comprising a plurality of spaced photosensitive regions for receiving and converting light energy into electric energy; and
a light leveling element disposed above the photovoltaic panel, the light leveling element comprising a base, a plurality of first lenses and a plurality of second lenses, the first lenses being arranged on a central portion of the base, and the second lens being arranged on a peripheral portion of the base, the first and second lenses being vertically aligned with the respective photosensitive regions, refraction indices of the first lenses being less than that of the second lenses.

2. The photovoltaic assembly as claimed in claim 1, wherein each of the photosensitive regions comprises a p-type semiconductor layer and an n-type semiconductor layer.

3. The photovoltaic assembly as claimed in claim 2, wherein the p-type semiconductor layer is made of a material selected from a group consisting of single-crystal silicon, amorphous silicon, polycrystalline silicon, gallium arsenide, indium phosphide, indium gallium phosphide, cadmium telluride, and copper indium selenide.

4. The photovoltaic assembly as claimed in claim 2, wherein the n-type semiconductor layer is made of a material selected from a group consisting of single-crystal silicon, amorphous silicon, polycrystalline silicon, gallium arsenide, indium phosphide, indium gallium phosphide, cadmium telluride, and copper indium selenide.

5. The photovoltaic assembly as claimed in claim 2, wherein the photovoltaic panel further comprises a pair of electrodes electrically connected to the p-type semiconductor layer and the n-type semiconductor layer.

6. The photovoltaic assembly as claimed in claim 5, wherein the electrodes are made of aluminum, silver or copper.

7. The photovoltaic assembly as claimed in claim 1, wherein the photosensitive regions are equidistantly spaced.

8. The photovoltaic assembly as claimed in claim 1, wherein the photosensitive regions are arranged in columns and rows.

9. The photovoltaic assembly as claimed in claim 1, further comprising a converging lens disposed above the light leveling element, and a diverging lens disposed between the converging lens and the light leveling element.
